(19) United States
(12) Patent Application Publication
(10) Pub. No.: US 2008/0050209 A1
(43) Pub. Date: Feb. 28, 2008

(54) CONDUCTIVE MEMBER SUPPLY APPARATUS AND CONDUCTIVE MEMBER SUPPLY METHOD

(75) Inventors: Toru Mizuno, Tokyo (JP); Kazuaki Takanuki, Tokyo (JP); Tatsuya Wagou, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TDK CORPORATION, Tokyo (JP)

(21) Appl. No.: 11/842,644

(22) Filed: Aug. 21, 2007

(30) Foreign Application Priority Data
Aug. 23, 2006 (JP) 2006-226444
Jun. 29, 2007 (JP) 2007-172109

(51) Int. Cl. B65G 53/12; H01L 21/67

(52) U.S. Cl. 414/217; 414/17

(57) ABSTRACT

A conductive member supply apparatus including a reservoir portion containing an internal space in which the conductive members are stored and a first gas-passing aperture communicating with the internal space, an alignment portion including an alignment path in which the conductive members are arranged in a row and which communicates with the internal space, and a second gas-passing aperture communicating with the alignment path, a stopper for closing/opening the alignment path, first gas supply unit which supplies gas to the alignment path from the first gas-passing aperture and through the internal space, second gas supply unit which supplies gas to the aligning direction of the conductive members from the second gas-passing aperture, and control unit which activates the first gas supply unit to supply gas in a state where the stopper is closed, wherein a distance between the second gas-passing aperture and the stopper along a direction of the alignment is substantially within a range of from a dimension of one conductive member to a dimension of one and a half conductive members.

### BACKGROUND OF THE INVENTION

1. Field of the Invention

The present invention relates to a conductive member supply apparatus and a conductive member supply method, for supplying one by one a small conductive member, to be employed for electrical connection between electrodes of a small electronic component.

2. Related Background Art

In a producing process of a magnetic head or the like, a connection between an electrode of a magnetic head slider and an electrode of a flexure is achieved by a soldering with a solder ball. More specifically, both electrodes are positioned with an angle of 90° therebetween, and a small conductive member is positioned between these electrodes and is fused for example by a heat ray thereby effecting the electrical connection between these electrodes. In the following, a prior soldering apparatus, provided with a conductive member supply apparatus, will be described with reference to the accompanying drawings.

FIG. 15 is a partial cross-sectional view of a prior soldering apparatus 601. The soldering apparatus 601 is provided with an optical system 603 such as a laser oscillator for fusing a solder ball 615, a solder ball supply portion 605 for individually supplying the solder ball 615, a nozzle end portion 607 for supporting the solder ball 615 in a solid state, and a gas supply part 611 for supplying the interior of the nozzle end portion 607 with nitrogen gas.

The solder ball supply portion 605 includes a solder ball moving board 613 of a rotatable disc shape. The solder ball moving board 613 is provided, on an external periphery thereof, with plural ball support holes 617, and each of the ball support holes 617 supports a solder ball 615. When a ball support hole 617 comes to a position matching an unillustrated hole provided in a bottom part of a ball reservoir 619, a solder ball 615 is supplied from the ball reservoir 619 and supported in the ball support hole 617.

When the solder ball moving board 613 is rotated to a position where the ball support hole 617 matches a gas supply path 621, the solder ball drops through the gas supply path 621 to the end portion 607, whereby the solder ball 615 is supported in the vicinity of an aperture 609 of the end portion 607.

The solder ball 615, supported in the vicinity of the aperture 609 of the end portion 607, is irradiated by a laser of the optical system 603, whereby the solder ball 615 is fused to achieve a soldering between an electrode 625 of a magnetic head slider 623 and an electrode 629 of a flexure 627 (cf. Japanese Patent Application Laid-Open No. 2002-170351 (for example paragraphs [0116] to [0125] and FIG. 20)). Also Japanese Patent Application Laid-Open No. 2005-079492 discloses a structure of mechanically supplying a solder ball from plural solder balls, supported in a reservoir portion such as the solder ball moving board illustrated in FIG. 15.

The soldering apparatus 601 of Japanese Patent Application Laid-Open No. 2002-170351 utilizes the solder ball moving board 613, in order to separate and convey a solder ball, among the plural solder balls 615 stored in the solder ball reservoir 619, to the end portion 607. However, along with the recent miniaturization of electronic components, the conductive member used for connecting the electrodes thereof has become very small. It is therefore becoming difficult to mechanically separate and convey a solder ball, as in the case of the solder ball moving board 613. For example, the solder ball 615 may be clogged or pinched between the solder ball moving board 613 and a main body of the solder ball supply apparatus including the solder ball moving board 613, whereby the solder ball may be deformed or broken.

Also in the solder ball moving board 613, the formation of the solder ball support hole 617 with such a high dimensional precision as to securely support only one solder ball may elevate the manufacturing cost of the apparatus itself.

### SUMMARY OF THE INVENTION

In consideration of the foregoing, an object of the present invention is to provide a conductive member supply apparatus and a conductive member supply method, capable of supplying securely one small conductive member, utilized in small electronic components, to a next process step.

The aforementioned object is accomplished, according a first aspect of the conductive member supply apparatus of the present invention, by a conductive member supply apparatus, including a reservoir containing an internal space in which conductive members are preserved and a first gas-passing aperture communicating with the internal space, an alignment portion containing an alignment path for arranging the conductive members in a row and a second gas-passing aperture communicating with the alignment path, a stopper for close/opening the alignment path, first gas supply unit which supplies gas from the first gas-passing aperture through the internal space to the alignment path, second gas supply unit which supplies gas from the second gas-passing aperture into the alignment path, and control unit which activates the first gas supply unit, in a state where the stopper is closed, to execute a gas supply thereby introducing the conductive members into the alignment path, and which activates the second gas supply unit to supply the alignment path with the gas, wherein a distance between the second gas-passing aperture and the stopper along the direction of alignment is substantially within a range of from the dimension of one conductive member to that of one and a half conductive members.

Also the aforementioned object is accomplished, according a first aspect of the conductive member supply method of the present invention, by a conductive member supply method which supplies conductive members stored in an internal space of a reservoir, one by one from an alignment path of an alignment portion communicating with the internal space, the method including an alignment step of supplying gas, in a state where the alignment path is closed by a stopper, to the conductive members stored in the internal space from the first gas-passing aperture communicating with the internal space thereby arranging the conductive members in a row in the alignment path of the alignment portion, a separation step of supplying the conductive members, aligned in the alignment step, with gas from a second gas-passing aperture of which a distance from the stopper along the direction of alignment of the conductive members is substantially within a range of from the dimension of one conductive member to that of one and a half conductive members, thereby separating a single conductive member, and a step of opening the stopper, and supplying gas from the second gas-passing aperture to discharge the single conductive member.

In the present specification, the conductive member means a member formed by a metal or alloy material such as solder or gold, and capable of electrically connecting members to be connected. The shape of such conductive member is not limited to a spherical shape but also includes other shapes such as a cubic shape and a conical shape.

### BRIEF DESCRIPTION OF THE DRAWINGS

FIGS. 1A, 1B, 1C, 1D and 1E are partial cross-sectional views illustrating operations steps of a solder ball supply apparatus constituting a first exemplary embodiment of the present invention.

FIG. 2 is a flow chart illustrating a solder ball supply step in the first embodiment.

FIG. 3 is a partial cross-sectional view illustrating a solder ball supply apparatus in a second exemplary embodiment of the present invention.

FIG. 4 is a flow chart illustrating a solder ball supply step in the second embodiment.

FIG. 5 is a partial cross-sectional view illustrating a solder ball supply apparatus in a third exemplary embodiment of the present invention.

FIG. 6 is a flow chart illustrating a solder ball supply step in the third embodiment.

FIG. 7 is a schematic view of a soldering apparatus of an example 1.

FIG. 8 is a partial cross-sectional view illustrating a solder ball supply portion and a nozzle in FIG. 7.

FIG. 9 is a magnified view of a portion IX in FIG. 8.

FIG. 10 is a partial cross-sectional view illustrating a solder ball supply portion and a nozzle in an example 2.

FIG. 11 is a magnified view of a portion XI in FIG. 10.

FIG. 12 is a cross-sectional view of a principal portion of a solder ball supply apparatus of an example 3.

FIG. 13 is a timing chart of a first operation pattern of the example 3.

FIG. 14 is a timing chart of a second operation pattern of the example 3.

FIG. 15 is a partial cross-sectional view of a prior soldering apparatus.

### DETAILED DESCRIPTION OF THE PREFERRED EMBODIMENTS

Now, the conductive member supply apparatus and the conductive member supply method of the present invention will be described by exemplary embodiments and examples with reference to the accompanying drawings. In the accompanying drawings, like portions are represented by like symbols.

### Exemplary Embodiment 1

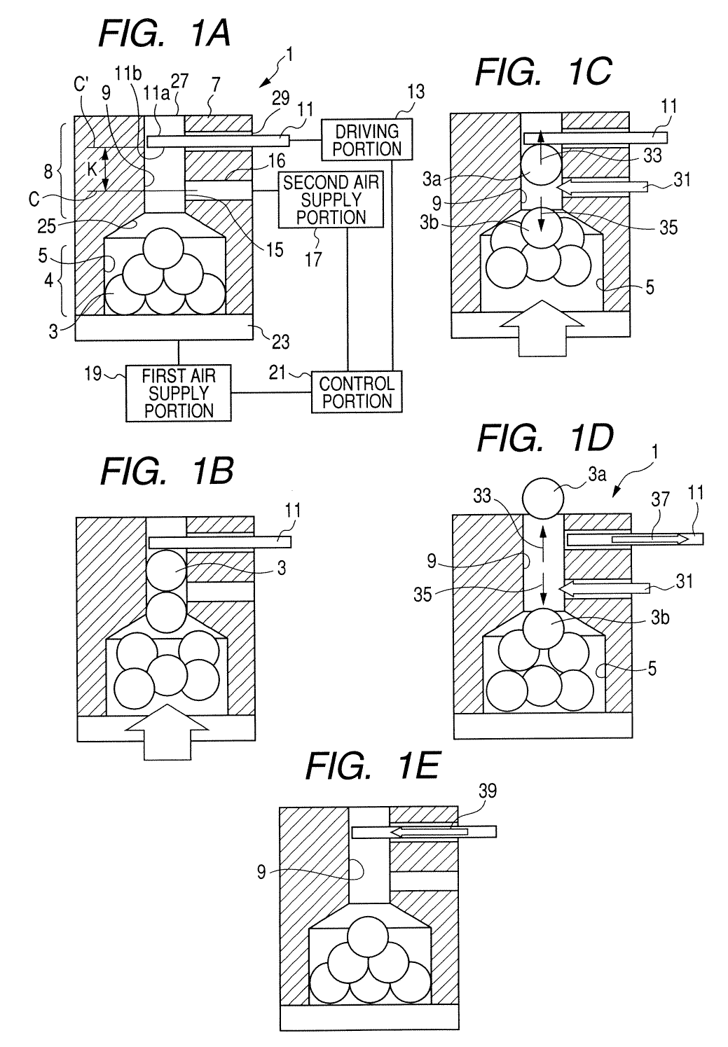

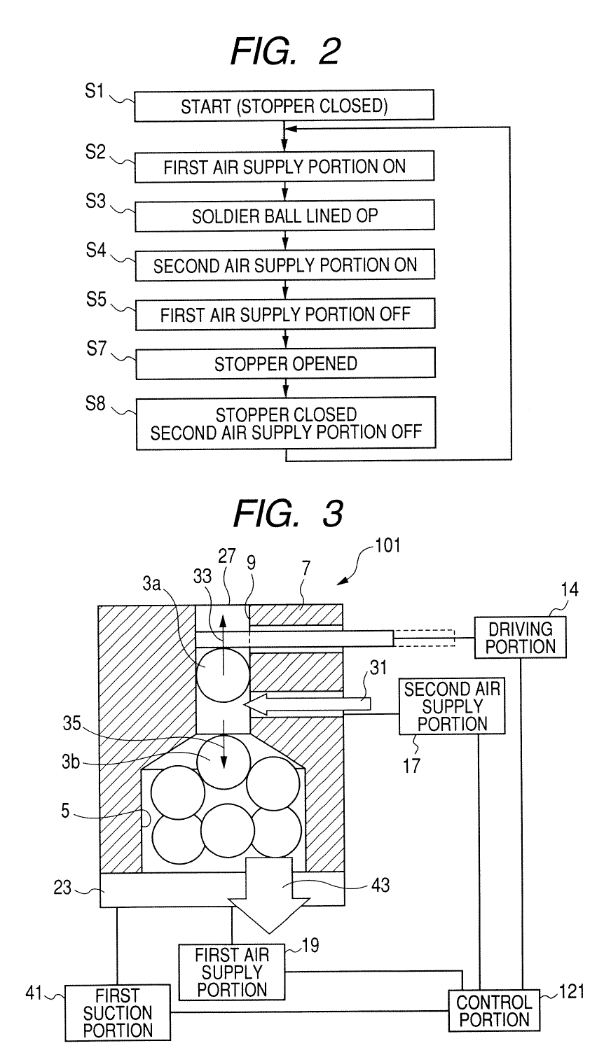

The embodiment 1 is an application of the conductive member supply apparatus to a solder ball supply apparatus. FIGS. 1A to 1E are partial cross-sectional views, illustrating a step, in the solder ball supply apparatus of the first embodiment of the present invention, of separating and supplying a solder ball from other solder balls. For the purpose of clarity, components of the solder ball supply apparatus are illustrated only in FIG. 1A but omitted in FIGS. 1B to 1E. FIG. 2 is a flow chart showing steps of a solder ball supply method utilizing the solder ball supply apparatus illustrated in FIGS. 1A to 1E.

As illustrated in FIG. 1A, a solder ball supply apparatus 1 is provided with a main body 7 of the apparatus, including a reservoir 4 having an internal space 5 for storing solder balls 3 which are spherical conductive members, and an alignment portion 8 having an alignment path 9 communicating with the internal space 5; a stopper 11 for opening or closing the alignment path 9; a first air supply portion (first gas supply unit) 19 for supplying air to a first gas-passing aperture (first gas supply path) formed by a bottom block to be explained later; a second air supply portion (second gas supply unit) 17 for supplying air to a second gas-passing aperture 15 communicating with the alignment path 9, and a control portion (control unit) 21 for driving the first air supply portion 19 and the second air supply portion 17 at predetermined timings. The present embodiment further includes, though not an essential component, a drive portion 13 for driving the stopper 11 for opening or closing the alignment path 9, and the stopper 11 is operated by the drive portion 13 by a command from the control portion 21.

In the following, each component of the solder ball supply apparatus 1 will be described in detail. The reservoir 4 is constituted of a lower portion of the main body 7 of a substantially cylindrical shape, and the solder balls 3 are stored in an internal space 5, defined by an internal peripheral surface thereof. The alignment portion 8 is constituted of an upper portion of the main body 7 of the apparatus, and includes an alignment path 9 which is defined by an internal peripheral surface thereof and which communicates with the internal space 5.

The internal space 5 of the reservoir 4 has an internal diameter larger than an internal diameter of the alignment path 9 of the alignment portion 8, and the internal space 5 and the alignment path 9 are connected by a tapered portion 25. The other end of the alignment path 9 constitutes an aperture 27 of the main body 7, open to the exterior. The internal diameter of the alignment path 9 is selected slightly larger than the external diameter of the solder ball 3. Therefore, when plural solder balls 3 enters the alignment path 9, the solder balls 3 are arranged in a row along the longitudinal direction thereof (hereinafter also referred to as an alignment direction of the solder balls). In the present embodiment, when the stopper 11 is closed, solder balls (3a, 3b) can be arranged in a row within the alignment path 9.

Also in a substantially vertical direction in the alignment path 9 of the main body 7 of the apparatus, there is provided a hole or a stopper accommodating path 29. The stopper accommodating path 29 accommodates the stopper 11, so as to allow a sliding motion of the stopper 11. The stopper accommodating path 29 is connected, at an end thereof, to the alignment path 9 and constitutes, at the other end, an aperture communicating with the exterior of the apparatus.

Also a second gas-passing aperture 15 is provided in the alignment path 9, below, in the alignment direction, the stopper accommodating path 29 in the main body 7 of the apparatus. The second gas-passing aperture 15 is connected to a second gas supply path 16 extending to the alignment path 9, and the second gas supply path 16 communicates, at an end thereof, with the alignment path 9 and constitutes, at the other end, an aperture open to the exterior of the main body 7 of the apparatus. The second gas supply path 16 extends in a direction substantially perpendicular to the extending direction of the alignment path 9.

The stopper accommodating hole 29 of the main body 7 of the apparatus accommodates a rod-shaped stopper 11 having such a dimension as to be slidable therein. A distal end portion 11a of the stopper 11 can enter the alignment path 9 thereby closing the alignment path 9. In a closed position where the end portion 11a closes the alignment path 9 (cf. FIGS. 1A and 1B), the dimensions of the components need only such that the movement of the solder balls 3 is inhibited. In the present embodiment, as the alignment path 9 has a substantially circular cross section, the air can pass through the alignment path 9 even when the stopper 11 protrudes in the alignment path 9 to close the alignment path 9.

The stopper 11 is connected to a known drive portion 13 for driving the stopper 11, such as a motor or a piezo actuator. The stopper 11 is moved by the drive portion 13 along a lateral direction in the FIGS. 1A to 1E, thus closing or opening the alignment path 9.

It is preferable that a minimum length K, between a center line C of the second gas supply path 16 of a substantially circular cross section and a line C′ parallel to the center line C and passing through a lower end 11b of the stopper 11, is so selected as equal to a range from the diametrical length of one solder ball 3 to one and a half times thereof.

The second air supply path 16 is connected to a second air supply portion 17 for supplying a compressed air. The positional relationship of the second air supply path 16 and the stopper 11 as described above enables to securely separate, by the compressed air from the second air supply portion 17, the solder ball 3a stopped by the stopper 11 from other solder balls 3b.

Also the bottom block 23, mounted on a lower end, in FIGS. 1A to 1E, of the main body of the apparatus, is formed by a porous member such as of a sintered metal. Fine penetrating pores of the porous member constitute the first gas supply path. The bottom block 23 is connected to a first air supply portion 19. Therefore, the air from the first air supply portion 19 is supplied, through the bottom block 23, into the interior of the internal space 5.

The solder ball supply apparatus 1 is further provided with a control portion 21. The control portion 21 is connected to the drive portion 13, the first air supply portion 19 and the second air supply portion 17. Drive signals from the control portion 21 are supplied to the drive portion 13, the second air supply portion 17 and the first air supply portion 19, which can thus be activated at predetermined operation timings.

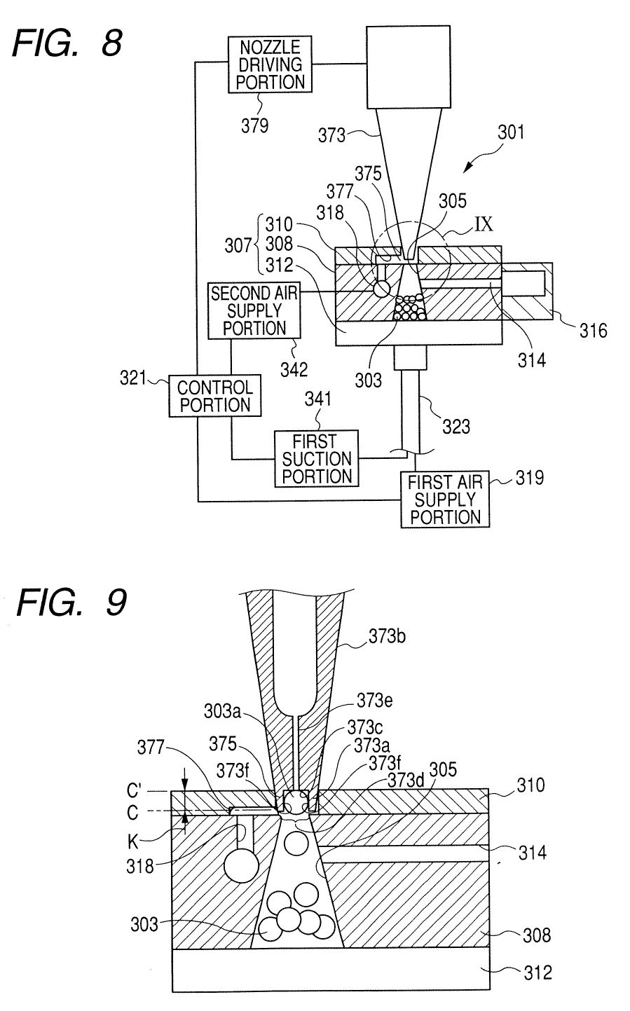

Now the functions of the solder ball supply apparatus of the aforementioned configuration will be described. At first, in the internal space 5 of the solder ball supply apparatus 1, plural solder balls 3 are loaded through an unillustrated solder ball filling hole (cf. member 314 in FIG. 8) (FIG. 1A). The stopper 11 is in a state of closing the alignment path 9 (S1 in FIG. 2).

Executed next is a step of aligning the solder balls. In response to a drive signal from the control portion 21, the first air supply portion 19 is activated to supply air, through the bottom block 23, into the internal space 5 (S2 in FIG. 2). The air flows upwards from the bottom block 23, whereby the solder balls 3 float and are guided into the alignment path 9. The solder balls 3 guided into the alignment path 9 are stopped by the stopper 11 and are aligned within the alignment path 9 (FIG. 1B, S3 in FIG. 2). The tapered portion 25, formed between the internal space 5 and the alignment path 9, allows to efficiently guide the solder balls 3, present in the internal space 5, into the alignment path 9.

Subsequently executed is a step of separating the solder ball. In response to a drive signal from the control portion 21, the second air supply portion 17 is activated (S4 in FIG. 2) to supply an air flow 31 from the second gas-passing aperture 15 into the alignment path 9. The air flow 31 is branched in the alignment path 9, as illustrated in FIG. 1C, into an upward flowing air 33 and a downward flowing air 35. By the air flow 31, the solder balls 3a and 3b, which are adjacent in the alignment path 9, are separated from each other. Thus, the first solder ball 3a, at the head of the ball row and in contact with the stopper 11, is separated from the second solder ball 3b succeeding thereto. Then, the upper solder ball 3a, among the adjacent solder balls 3, is maintained in a state in contact with the stopper 11 by the upward flowing air 33. On the other hand, the lower solder ball 3b is returned into the internal space 5 by the downward flowing air 35. As a result, a single solder ball 3a is separated and supported in the alignment path 9.

Next executed is a step of opening the stopper and discharging the solder ball, as illustrated in FIG. 1D. In this step, while the supply of the air flow 31 from the second air supply portion 17 is retained, the activation of the first air supply portion 19 is terminated by a signal from the control portion 21 (S5 in FIG. 2), thereby terminating the air supply from the side of the bottom block 23. Then a drive signal from the control portion 21 is given to the drive portion 13 to displace the stopper 11 rightward in FIG. 1D (indicated by an arrow 37), thereby opening the alignment path 9 (S7 in FIG. 2). In this state, by the upward flowing air 33 in the alignment path 9, the solder ball 3a moves toward the aperture 27 of the alignment path 9, and is conveyed to a next process step. On the other hand, the solder balls present in the internal space 5, including the solder ball 3b, are retained within the internal space 5 by the downward flowing air 35 in the alignment path 9 and are not erroneously discharged to the exterior of the solder ball supply apparatus 1 through the alignment path 9.

Finally executed is a step of closing the stopper as illustrated in FIG. 1E. A drive signal from the control portion 21 is given to the drive portion 13 to displace the stopper 11 leftward (as indicated by an arrow 39), thereby closing the alignment path 9 (S8 in FIG. 2). After or simultaneously with the closing, a stop signal from the control portion 21 terminates the operation of the second air supply portion 17, thus terminating the air supply (S8 in FIG. 2). Thereafter, the solder ball supply is executed on the remaining solder balls 3 by repeating the steps starting from S2.

### Exemplary Embodiment 2

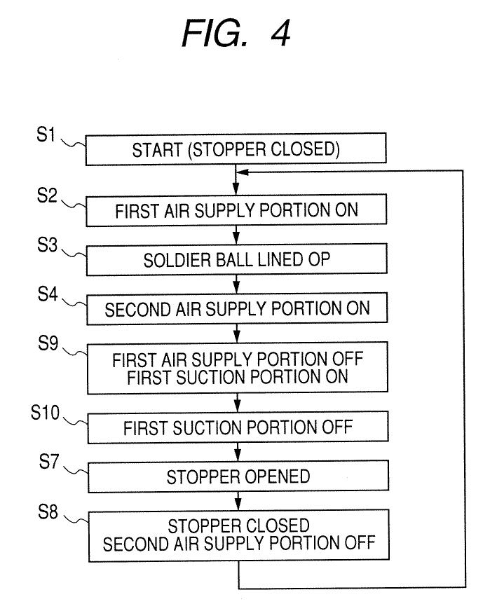

A second embodiment of the conductive member supply apparatus of the present invention is a solder ball supply apparatus, provided further with a suction portion (suction unit) in addition to the solder ball supply apparatus of the first embodiment. FIG. 3 is a partial cross-sectional view of the solder ball supply apparatus 101 constituting the second embodiment, and FIG. 4 is a flow chart showing steps of a solder ball supply method utilizing the solder ball supply apparatus illustrated in FIG. 3. As the constitution of the solder ball supply apparatus 101 is similar to that of the solder ball supply apparatus 1 illustrated in FIGS. 1A to 1E, different portions only will be described in the following. Therefore, portions not explained particularly have structures similar to those in the first embodiment.

In the present embodiment, the bottom block 23 of the main body 7 of the apparatus is connected to a first suction portion 41. The first suction portion 41, having an unillustrated suction source, is provide the internal space 5 with a suction force through the bottom block 23. The first suction portion 41 is connected to a control portion 121, and the first suction portion 41 is activated in response to a drive signal from the control portion 121 thereby providing the internal space 5 with a suction force.

The control portion 121 is also connected, as in the control portion 21 of the conductive member supply apparatus 1 in FIG. 1, to the first and second air supply portions 17, 19 and the drive portion 13, and can therefore control these elements at predetermined operation timings.

Now the functions of the solder ball supply apparatus 101 of the second embodiment will be described. A solder ball loading step and an alignment step for aligning the solder balls are executed in the same manner as illustrated in FIGS. 1A and 1B in the first embodiment (S1 to S3 in FIG. 4).

Then the first air supply portion 19 is stopped to terminate the air supply into the internal space 5. As illustrated in FIG. 3, a next solder ball separating step is different from that in the first embodiment. In the solder ball separating step of the second embodiment, a drive signal from the control portion 121 is supplied to the second air supply portion 17 to supply an air flow 31 (S4 in FIG. 4). Then, the first air supply portion 19 is stopped by the control portion 121 (S9 in FIG. 4), and the first suction portion 41 is activated to apply a suction force in the internal space 5 (S9 in FIG. 4). In such structure, in addition to that the air flow 31 is branched in the alignment path 9 into a downward flowing air 35 and an upward flowing air 33, an air flow 43 is formed by the suction force by the first suction portion 41. Therefore, while the solder ball 3b is returned into the internal space 5, one solder ball 3a is separated and supported in the alignment path 9. This constitution, in comparison with the first embodiment, securely forms an air flow 43 in the internal space 5 excluding the solder ball 3a, thereby realizing the solder ball separating step at a higher speed.

Next executed is a step of discharging a solder ball (cf. FIG. 1D). In this step, the operation of the first suction portion 41 is terminated (S10 in FIG. 4). Then, while the supply of the air flow 31 from the second air supply portion 17 is retained, and the stopper 11 is displaced rightward (S7 in FIG. 4), thereby opening the alignment path 9 (cf. FIG. 1D). In this state, by the upward flowing air 33 in the alignment path 9, the solder ball 3a moves toward the aperture 27 of the alignment path 9, and is conveyed to a next process step. On the other hand, the solder balls present in the internal space 5, including the solder ball 3b, are retained within the internal space 5 by the downward flowing air 35 in the alignment path 9 and are not erroneously discharged to the exterior of the solder ball supply apparatus 1 through the alignment path 9.

Finally executed is a step of closing the stopper (cf. FIG. 1E). A drive signal from the control portion 121 is given to the drive portion 13 to displace the stopper 11 leftward, thereby closing the alignment path 9 (S8 in FIG. 4). After or simultaneously with the closing, a stop signal from the control portion 121 terminates the operation of the second air supply portion 17 (S8 in FIG. 4), thus terminating the air supply.

### Exemplary Embodiment 3

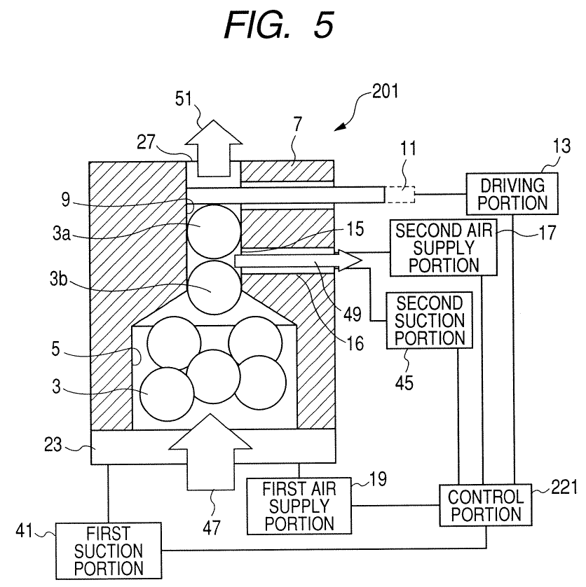

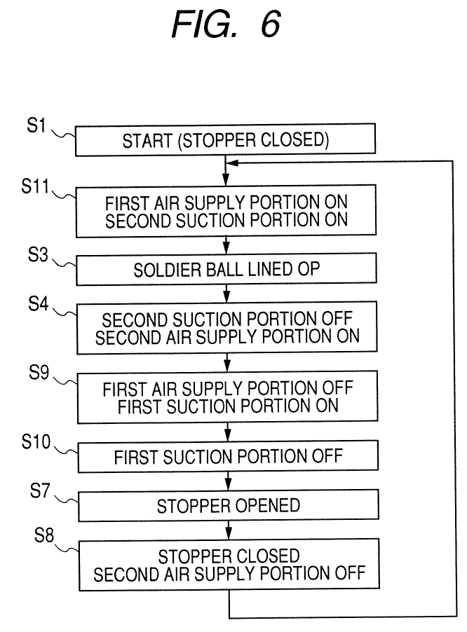

A third embodiment of the conductive member supply apparatus of the present invention is a solder ball supply apparatus, provided further with another suction portion (suction unit) in addition to the solder ball supply apparatus 101 of the second embodiment. FIG. 5 is a partial cross-sectional view of the solder ball supply apparatus 201 constituting the third embodiment, and FIG. 6 is a flow chart showing steps of a solder ball supply method utilizing the solder ball supply apparatus illustrated in FIG. 5. As the constitution of the solder ball supply apparatus 201 is similar to that of the solder ball supply apparatus 101 illustrated in FIG. 3, different portions only will be described in the following. Therefore, portions not explained particularly have structures similar to those in the second embodiment.

In the present embodiment, a second suction portion 45 is newly connected to the second gas supply path 16 in the main body 7 of the apparatus. The second suction portion 45 is used for providing the interior of the alignment path 9 with a suction force, through the second gas supply path 16 and the second gas-passing aperture 15. The second suction portion 45 is connected to a control portion 221, and, in response to a drive signal from the control portion 221, the second suction portion 45 is activated to provide the interior of the second gas-passing aperture 15 with a suction force.

Like the control portion 121 of the conductive member supply apparatus 101 shown in FIG. 3, the control portion 221 of the conductive member supply apparatus 201 in the third embodiment is also connected to the first and second air supply portions 17, 19, the first suction portion 41 and the drive portion 13, and can therefore control these elements at predetermined operation timings.

Now the operations of the solder ball supply apparatus 201 of the third embodiment will be described. At first, in the same manner in the first embodiment as illustrated in FIG. 1A, the loading of solder balls is executed in a state where the alignment path 9 is closed by the stopper 11 (S1 in FIG. 6).

The next solder ball alignment step is different, as illustrated in FIG. 5, from that in the first and second embodiments. In response to a drive signal from the control portion 221, the first air supply portion 19 and the second suction portion 45 are activated (S11 in FIG. 6). In the solder ball apparatus 201, there is formed an air flow 51 which passes the bottom block 23, the internal space 5, the alignment path 9 and the aperture 27 and is directed toward the exterior of the solder ball apparatus 201, whereby the solder balls 3 are aligned (S3 in FIG. 6). Also, as a suction force is given to the second gas-passing aperture 15 by means of the second suction portion 45, a part of the air passing through the internal space 5 and reaching the alignment path 9 forms an air flow (as indicated by an arrow 49) into the second gas supply path 16. Therefore, the displacement of the solder balls 3 into the alignment path 9 can be realized promptly and securely. Also this constitution enables a faster introduction of the solder balls into the alignment path 9, in comparison with the first and second embodiments, which do not utilize the second suction portion 45.

Next executed is a solder ball separating step. In this step, the operation of the second suction portion 45 is terminated, and the second air supply portion 17 is activated (S4 in FIG. 6). Then, as in the second embodiment, the control portion 221 terminates the operation of the first air supply portion 19 and activates the first suction portion 41 (S9 in FIG. 6), thereby supplying air (cf. symbol 31 in FIG. 3) and applying a suction force in the internal space 5. In such structure, an air flow (cf. symbol 43 in FIG. 3) is formed by a downward moving air (cf. symbol 35 in FIG. 3) branched from the air flow (cf. 31 in FIG. 3) in the alignment path 9 and by the suction force caused by the first suction portion, whereby the solder balls 3 other than the solder ball 3a are returned to the internal space 5. As a result, a single ball 3a is separated and supported in the alignment path 9.

Next executed is a step of opening the stopper and discharging the solder ball (cf. FIG. 1D). In this step, while the air supply (cf. symbol 31 in FIG. 3) from the second air supply portion 17 is maintained, the operation of the first suction portion 41 is terminated (S10 in FIG. 6), thereby terminating the suction from the side of the bottom block 23. Then a drive signal is given from the control portion 221 to the drive portion 13 to displace the stopper 11 rightward thereby opening the alignment path 9 (as illustrated by a broken line in FIG. 5). In this state, by the upward flowing air (cf. symbol 33 in FIG. 3) in the alignment path 9, the solder ball 3a moves toward the aperture 27 of the alignment path 9, and is discharged to a next process step. On the other hand, the solder balls present in the internal space 5, including the solder ball 3b, are retained within the internal space 5 by the downward flowing air (cf. symbol 35 in FIG. 3) in the alignment path 9 and are not erroneously discharged to the exterior of the solder ball supply apparatus 1 through the alignment path 9.

Finally executed is a step of closing the stopper (cf. FIG. 1E). A drive signal from the control portion 221 is given to the drive portion 13 to displace the stopper 11 leftward, thereby closing the alignment path 9 (S8 in FIG. 6). After or simultaneously with the closing, a stop signal from the control portion 221 terminates the operation of the second air supply portion 17 (S8 in FIG. 6), thus terminating the air supply.

In the second and third embodiments described above, the first or second suction portion provides the suction force respectively through the first or second gas-passing aperture, but it is naturally possible to provide a suction aperture corresponding to each of the first and second suction portions.

### Example 1

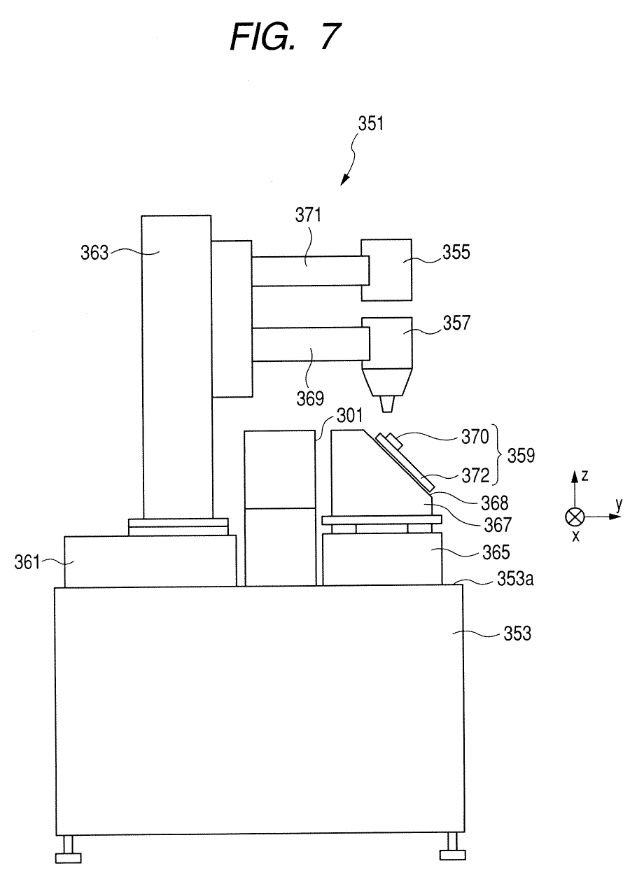

In the following, there will be described an example of applying the conductive member supply apparatus of the present invention to a soldering apparatus. FIG. 7 is a schematic view of the soldering apparatus, while FIG. 8 is a partial cross-sectional view illustrating a solder ball supply portion and a nozzle, and FIG. 9 is a magnified view of a portion IX in FIG. 8.

The soldering apparatus 351 includes a support base 353, a laser irradiation portion 355 for fusing the spherical solder ball, disposed on a work surface 353a of the support base 353, a suction portion 357 for supporting the solder ball by suction, an x-direction movable stage 365 movable along an x-axis direction and a y-direction movable stage 361 movable along a y-axis direction, both disposed on the work surface 353a of the support base 353, a work tray 367 fixed on an upper surface of the x-axis movable stage 365 and serving to convey a work 359, and a z-direction movable stage 363 movable along a z-axis direction and fixed on the y-direction movable stage 361.

The suction portion 357 is fixed to the z-direction movable stage 363 via an arm 369, and the nozzle arm 369 is rendered movable in a vertical direction in FIG. 7. Also the laser irradiation portion 355 is connected, like the suction portion 357, to the z-direction movable stage 363 through an irradiation portion support member 371. Therefore the suction portion 357 and the laser irradiation portion 355 are rendered movable in the vertical direction in the FIG. 7.

Also, since the z-direction movable stage 363 is fixed to the y-direction movable stage 361, the z-direction movable stage 363 is rendered movable in the y-axis direction (lateral direction in FIG. 7), and the laser irradiation portion 355 and the suction portion 357 are both rendered movable in the y-axis direction.

On the other hand, the laser irradiation portion 355 and the suction portion 357 may be moved in the x-axis direction (front-back direction to the plane of FIG. 7) by moving the work tray 367, which is fixed to the x-direction movable stage 365.

The work tray 367 has a work supporting surface 368 inclined to the vertical direction, and the work 359 is placed on the supporting surface 368 and is subjected to the connection between electrodes. In the present example, the work 359 is constituted of an electronic component employed in a hard disk, more specifically a flexure 372 on which a magnetic head slider 370 is mounted. The connection of an electrode of the magnetic head slider and an electrode of the flexure is executed by a soldering utilizing a solder ball. The both electrodes are disposed with an angle of 90° therebetween, and a solder ball is placed in a corner portion formed by these electrodes, and is fused for example by a heat ray thereby effecting the electrical connection between these electrodes.

A solder ball supply apparatus 301 is fixed in the upper surface 353a of the support base 353. Details of the solder ball supply apparatus 301 will be described with reference to FIGS. 8 and 9. FIG. 8 is a partial cross-sectional view illustrating a solder ball supply portion and a nozzle, and FIG. 9 is a magnified view of a portion IX in FIG. 8.

The solder ball supply apparatus 301, having a construction similar to that of the second embodiment, includes a main body 307 of the apparatus, a first air supply portion 319, a first suction portion 341, a second air supply portion 342, a nozzle 373 constituting a stopper, and a control portion 321. The solder ball supply apparatus 301 has a construction and an operating mode (FIG. 4) similar to those of the second embodiment, unless specified otherwise.

The main body 307 of the apparatus includes a central block 308 of a substantially rectangular parallelepiped shape, and an upper block 310 and a bottom block 312 of a plate shape, respectively mounted on upper and lower surfaces of the central block in the thickness direction thereof. The central block 308 has a penetrating hole which defines an internal space 305 for storing solder balls 303, and which is enlarged toward the lower side in the thickness direction. Also provided is a solder replenishing hole 314, which extends in a substantially horizontal direction in the central block 308 and which connects the internal space 305 and the exterior. The solder balls 303 are loaded, through this solder replenishing hole 314, into the internal space 305. Except at the loading of the solder balls, the solder replenishing hole 314 is closed by a replenishing hole cover 316, which is screwed on the central block 314.

The central block 308 is further provided with a second gas-passing path 318. The second gas-passing path 318 extends, from a lateral face of the central block 308, in a front-rear direction of the drawing, then is bent toward the upper surface in the thickness direction and opens on the upper surface.

The upper block 310 mounted on the upper surface of the central block 308 includes a nozzle accommodating hole 375 in which an end portion of a nozzle 373 to be described later is inserted, and a groove 377 which is connected to the nozzle accommodating hole 375 and extends towards left in FIG. 8. When the upper block 310 is mounted on the central block 308, a horizontal path extending towards right is formed by the groove 377 and the upper surface of the central block 308. This horizontal path and the aforementioned second gas-passing path 318 constitute the second gas supply path. Therefore, the air from the second air supply portion 342 is supplied, through the second gas supply path, to the nozzle accommodating hole 375.

The bottom block 312, mounted on the lower surface of the central block 308, is formed by a sintered member (porous member). The bottom block 312 is connected to the first air supply portion 319 and the first suction portion 341, through a tube 323. In the above-described construction, the air from the first air supply portion 319 and the suction force from the first suction portion 341 are provided to the internal space 305, through the fine pores of the bottom block 312 constituting the first gas-passing aperture.

A nozzle 373, in which the solder balls 303 are supported by suction, has a shape pointed toward the end, and functions as a stopper of the solder ball supply apparatus 301. The nozzle 373 includes a solder ball support portion 373a and a nozzle main body 373b. The solder ball support portion 373a, constituting the distal end portion of the nozzle 373, includes a peripheral wall portion 373f which defines an aperture 373d of the nozzle 373 and executes positioning of the solder ball 303 in a radial direction thereof, and a contact portion 373c which executes positioning of the solder ball upwards in the axial direction. An internal width of the peripheral wall portion 373f (aperture) is selected slightly larger than the external diameter of the solder ball 303a. Also a distance from the aperture 373d to the contact portion 373c, in the vertical direction when the nozzle 373 is maintained in a vertical position, is selected substantially same as the external diameter of the solder ball 303a. Therefore, the solder ball support portion 373a is so dimensioned as to contain only one solder ball 303a. Thus the solder ball support portion 373a serves as a stopper for the solder ball supply apparatus 301.

The nozzle main body 373b is provided with a suction air supply path 373e, penetrating the contact portion 373c of the solder ball support portion 373a and serving to provide a suction force. The suction air supply path 373e is connected to an unillustrated suction pump, and a suction force is supplied through the suction air supply path 373e to the solder ball support portion 373a thereby supporting the solder ball by suction. In the present example, in a state where the nozzle 373 is inserted into the nozzle accommodating hole 375, the nozzle 373, the nozzle accommodating hole 375 and the internal space 305 have substantially matching central axes.

Now the functions of the soldering apparatus 351 will be described briefly. At first, the work 359 is supplied to the work tray 367. FIG. 7 illustrates only one work 359, but it is naturally possible to adopt a construction for supporting plural works. More specifically, it is possible to match the number of nozzle 373 with the number of works and to execute the soldering operation on all the works 359 at the same time, or to repeat the soldering operation on the works by a single nozzle 373.

Next executed is a solder ball supply step of supplying the nozzle 373 of the suction portion 357 with the solder ball 303, by the solder ball supply apparatus 301. In the solder ball supply step, in response to a command from the control portion 321, the nozzle 373 is moved by the x-direction movable stage, the y-direction movable stage 361 and the z-direction movable stage 363 and is inserted into the nozzle accommodating hole 375 of the main body 307 of the apparatus. Thereafter, the solder ball is contained in the solder ball support portion 373a, in a similar manner as in the flow chart of the embodiment 2 illustrated in FIG. 4. A state where the nozzle 373 is inserted into the nozzle accommodating hole 375 corresponds to the state where the stopper is closed in the embodiment 2. Also the support portion 373a of the nozzle corresponds to the alignment path. A minimum length K, between a center line C of the groove 377 of a substantially circular cross section in the upper block 310 and a line C′ passing through a contact point of the solder ball 303a with the solder ball support portion 373a and parallel to the line C, is preferably so selected as substantially within a range of from the diameter of one solder ball 303a to one and a half times thereof.

Air is supplied from the first air supply portion 319 to the internal space 305, whereby plural solder balls 303 are made to float, and such solder balls 303 are introduced into the solder ball support portion 373a.

Then, air, for separating the solder ball 303a from other solder balls, is supplied from the second air supply portion 342 in the horizontal direction to the vicinity of the aperture 373d of the nozzle 373. Such air separates one solder ball 303a from other solder balls 303. Also simultaneous with or prior to the operation of the second air supply portion 342, the first air supply portion 319 is deactivated and the first suction portion 341 is activated, thereby providing the internal space 305 with a suction force. In this state, a part of the air supplied from the second air supply portion 342 is branched to form, in the internal space 305, a downward flow toward the bottom block 312. Thus other solder balls 303 are separated from the solder ball 303a and are returned to the internal space 305.

Then, in response to a command from the control portion 321, the first suction portion 341 is deactivated and the suction pump (not illustrated) of the nozzle 373 is activated to apply a suction air to the solder ball 303a, thereby attracting it in the solder ball support portion 373a.

Next executed is a conveying step of conveying the solder ball 303a to the work 359. More specifically, the nozzle 373 is moved upwards in the drawing from the nozzle accommodating hole 375, and the second air supply portion 342 is deactivated. The second air supply portion 342 is stopped after the nozzle 373 is moved away from the nozzle accommodating hole 375, in order to prevent attraction of other solder balls to the nozzle by maintaining the downward air flow in the internal space 305 by the second air supply portion 342.

Then the nozzle 373 is positioned at the corner portion formed by the electrode of the flexure 372 and the electrode of the head slider 370, by suitable movements of the y-direction movable stage 361, the z-direction movable stage 363 and the x-direction movable stage 365.

Finally executed is a bonding step. The laser irradiation portion 355 irradiates the solder ball 303a, supported in the solder ball support portion 373a of the suction portion 357 with a laser light, thereby fusing the solder ball 303a and executing a soldering of the electrode of the flexure 372 and the electrode of the head slider 370.

### Example 2

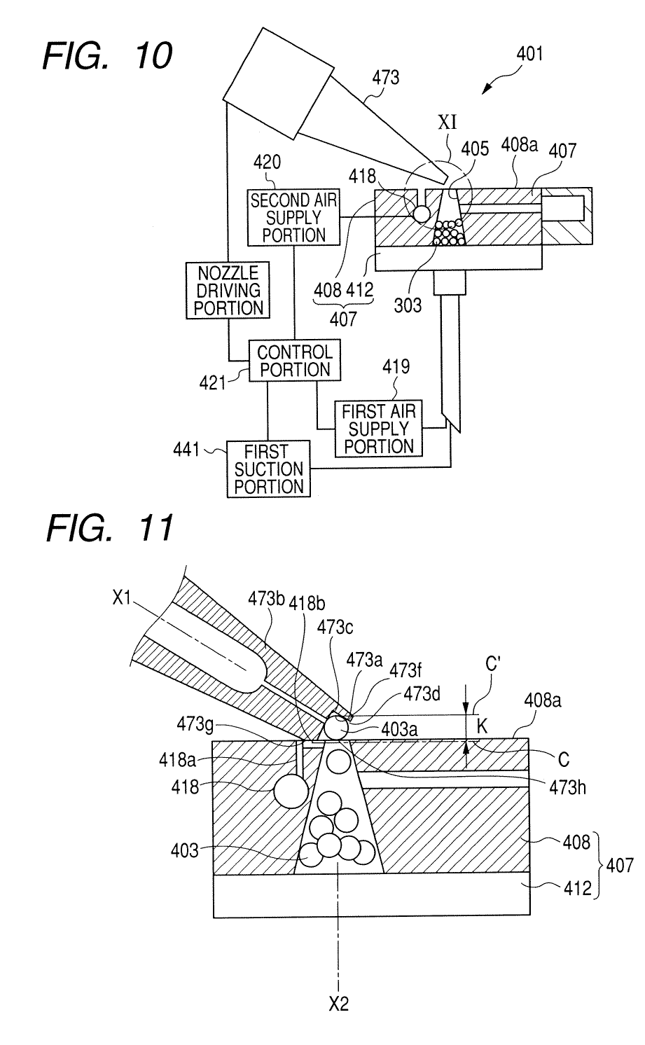

Example 2, as in Example 1, is an example in which the conductive member supply apparatus of the present invention is applied to a soldering apparatus. FIG. 10 is a partial cross-sectional view illustrating a solder ball supply portion and a nozzle, and FIG. 11 is a magnified view of a portion XI in FIG. 10.

The structure of Example 2 will be described only on portions different from those in Example 1. Therefore, structures and functions not particularly described are same as in Example 1.

The solder ball supply apparatus 401 includes a main body 407 of the apparatus, a first air supply portion 419, a first suction portion 441, a second air supply portion 420, a nozzle 473 of a suction portion (cf. 357 in FIG. 7) constituting a stopper, and a control portion 421.

The main body 407 of the apparatus includes a central block 408 of a substantially rectangular parallelepiped shape, and a bottom block 412 of a plate shape, mounted on a lower surface of the central block in the thickness direction thereof. Thus, different from Example 1, the upper block is not provided.

The central block 408 has a second gas supply path 418. The second gas supply path 418 is constituted of a second gas passing path 418a which extends in a front-rear direction in the drawing from a lateral face of the central block 408, further extends toward the upper surface in the thickness direction and opens at the upper surface, and a groove 418b which is formed on the upper surface 408a and is connected to the internal space 405.

A nozzle 473, in which the solder balls 403 are supported by suction, has a shape pointed toward the end, and functions as a stopper and an alignment path of the solder ball supply apparatus 401. The nozzle 473 includes a solder ball support portion 473a and a nozzle main body 473b. The solder ball support portion 473a, constituting the distal end portion of the nozzle 473, includes a peripheral wall portion 473f which defines an aperture 473d of the nozzle 473 and executes positioning of the solder ball 403a in a radial direction thereof, and a contact portion 473c which executes positioning of the solder ball upwards in the axial direction of the nozzle 473. It is different from Example 1 in that an inclined face 473g is formed on the external peripheral surface of the nozzle 473, and a notch 473h in the peripheral wall portion 473f is formed in continuation to the inclined face 473g. The inclined face 473g is contacted with the groove 418b of the central block 408a, thereby constituting the second gas supply path 418. Therefore, the nozzle 473 is disposed in such a position that a central axis X1 of the nozzle 473 and a central axis X2 of the internal space 405 mutually cross in an inclined relationship. Also the second gas supply path 418 is completed by contacting the nozzle 473 with the central block 408, whereby the air from the second air supply portion 420 is supplied into the internal space 403.

Furthermore, the solder ball support portion 473a has such a dimension, as in Example 1, as to contain only one solder ball 403a. Thus, the solder ball support portion 473a serves as an alignment path in the solder ball supply apparatus 401. Also the contact portion 473c and the peripheral wall portion 473f serve as a stopper in the solder ball supply apparatus 401. Also a minimum length K, between a center line C of the groove 418b of a substantially rectangular cross section and a line C′ passing through the upper end of the solder ball 403a and parallel to the line C, is preferably so selected as substantially within a range of from the diameter of one solder ball to one and a half times thereof.

The functions of the soldering apparatus 401 of the aforementioned structure are similar to those of Example 1, and will not, therefore, be described further.

### Example 3

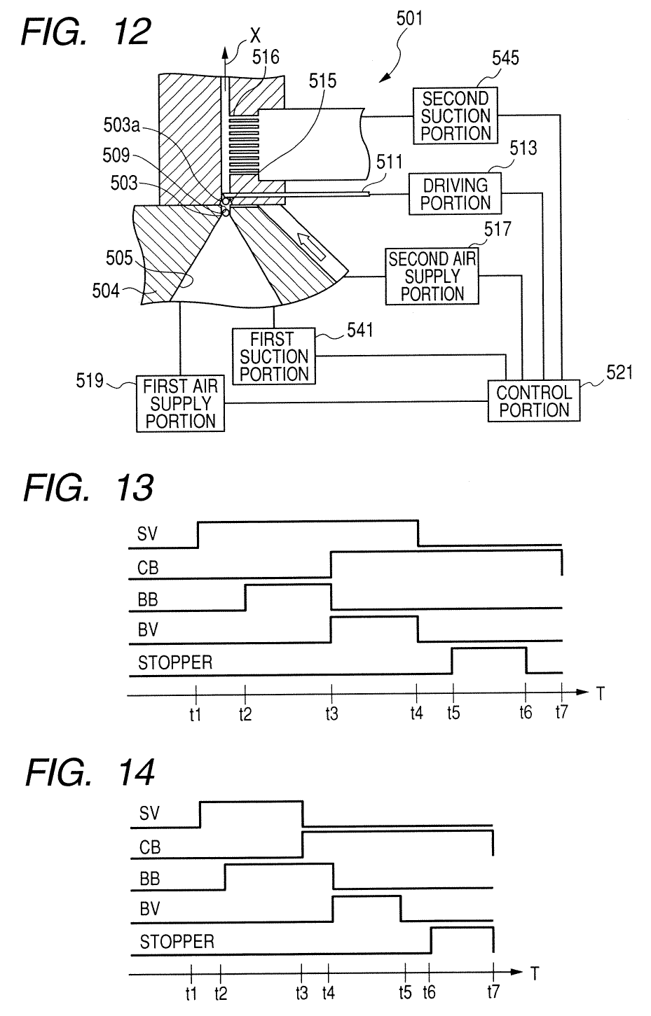

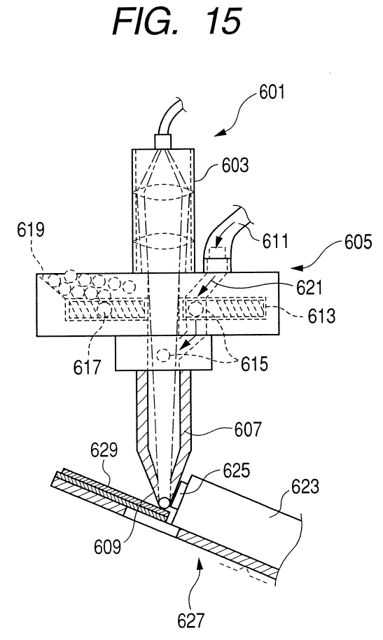

Example 3 is a variation of the solder ball supply apparatus of embodiment 3. FIG. 12 is a cross-sectional view of a principal part of the solder ball supply apparatus, FIG. 13 is a timing chart illustrating timings of a first operation condition, and FIG. 14 is a timing chart illustrating timings of a second operation condition.

The solder ball supply apparatus 501 of Example 3 is similar to the solder ball supply apparatus 201 illustrated in FIG. 5, except for a difference that the second suction portion 545 is disposed at a downstream side of the stopper 511, with respect to an advancing direction of the solder ball.

Difference also lies in facts that a second gas-passing aperture 515 and a second suction aperture 516 are provided in different positions of the alignment path 509 and that the second suction aperture 516 is provided in plural units and at a constant pitch along the extending direction of the alignment path 509.

Following conditions of experiment were adopted. The solder ball 503 had an external diameter of about 100 μm. Also the gas supplied from the first and second air supply portions 519, 517 was nitrogen gas. The environment in which the solder ball supply apparatus 501 was positioned was a room temperature of from 25.3 to 26.4° C. and a humidity of from 48.3 to 51.7%. The gas supplied from the first air supply portion 519 had a pressure of about from 50 to 80 kPa, and the gas supplied from the second air supply portion 517 had a pressure of about from 50 to 60 kPa. Also in order to avoid static charging (electrification) of the solder ball, an ionizer was provided in front of unillustrated regulators for regulating the gas flow rates in the first air supply portion 519 and the second air supply portion 517, thereby eliminating charge from the supplied nitrogen gas. Also a reservoir 504 defining the internal space 505 was connected to the ground.

The separation of solder balls was experimented in two operation timings, as illustrated in FIGS. 13 and 14. In FIGS. 13 and 14, SV on the ordinate indicates the operation of the second suction portion 545; CB indicates the operation of the second air supply portion 517; BB indicates the operation of the first air supply portion 519; BV indicates the operation of the first suction portion 541; and Stopper indicates the operation of the stopper 511. Also the abscissa indicates time (T).

The components were operated by the control portion 521 as illustrated in the timing chart of FIG. 13. At first the second suction portion 545 is activated at t1, and the first air supply portion 519 is activated at t2 to introduce the solder balls 503 into the alignment path 509. As the stopper 511 is closed in the initial state, the solder balls 503 are stopped by the stopper 511. Then the second air supply portion 517 is activated at t3 to separate the solder ball 503a from other solder balls 503. At t3, also the first air supply portion 519 is deactivated and the first suction portion 541 is activated. Thus an air flow is formed from the second gas-passing aperture 515 to the internal space 505, whereby the solder balls 503 other than the solder ball 503a are returned to the internal space 505. Then, at t4, the second suction portion 545 and the first suction portion 541 are deactivated while the operation of the second air supply portion 517 is maintained, whereby the air therefrom retains the solder ball 503a in the alignment path 509. Then, at t5, the stopper 511 is opened to advance the solder ball 503a in a direction indicated by an arrow x. Then, at t6, the stopper 511 is closed and the second air supply portion 517 is deactivated at last. This is to avoid that other solder balls 503 erroneously pass the stopper 511, while the stopper 511 is open. One cycle of this operation pattern required about 0.45 seconds.

In the second operation pattern illustrated in FIG. 14, the operations at t1 and t2 are same as those in FIG. 13. At t3, the second suction portion 545 is deactivated and the second air supply portion 517 is activated, thereby separating the solder ball 503a from other solder balls 503, aligned in the alignment path 509. At t4, the first air supply portion 519 is deactivated and the first suction portion 541 is activated, thereby returning the solder balls 503, other than the solder ball 503a, into the internal space 505. At t5, the first suction portion 541 is deactivated, and, at t6, the stopper 511 is opened, thereby executing an advancement in the x-direction over the stopper 511 by the air from the second air supply portion 517. Then, at t7, the second air supply portion 517 is deactivated and the alignment path 509 is closed by the stopper 511, whereby one cycle of the operations is terminated. In these timings of operations, one cycle required about 0.41 seconds.

This example of the present invention, in either timing chart, enabled a secure supply of a single solder ball in comparison with the construction mentioned in the background technology, and provided a sufficiently satisfactory time required for the supply operations.

In these embodiments and examples, the air supply portion may be constituted of a known pressure source capable of providing a pressurized gas, and the suction portion may be constituted of a vacuum source capable of sucking air. It is also possible to utilize a pressure source capable of switching a positive pressure and a negative pressure, as both the air supply portion and the suction portion.

The foregoing embodiments and examples employ a structure of supplying compressed air, to the solder balls aligned in the alignment path, from a substantially perpendicular direction through the gas-passing aperture, thereby separating a single solder ball from other solder balls, but the alignment path and the gas supply path need not necessarily be perpendicular with each other. It is only required to supply the compressed air from a direction having an inclination angle to the alignment path, in order to separate the solder balls.

Also the shape and the position of the stopper are not limited to those in the foregoing embodiments and examples.

The present invention, having a construction of separating and conveying one conductive member by means of air from the aligned conductive members, is capable of preventing a deformation or a breakage of the conductive member. As a result, regardless of the dimension of the conductive member, one conductive member can be securely supplied to the next step.

Also according to a second aspect of the conductive member supply apparatus of the present invention, gas is supplied by the second gas supply unit from the second gas-passing aperture into the alignment path, thereby separating, among the conductive members arranged in a row, a first conductive member at the head of the row and in contact with the stopper, from the succeeding second conductive member.

Also according to a third aspect of the conductive member supply apparatus of the present invention, there is further provided first suction unit which provides the internal space with a suction force, through the first gas-passing aperture provided in the reservoir.

Also according to a fourth aspect of the conductive member supply apparatus of the present invention, there is further provided second suction unit which provides the alignment path with a suction force, through the second gas-passing aperture provided in the alignment path.

Also according to a fifth aspect of the conductive member supply apparatus of the present invention, the stopper and the alignment path are formed by a nozzle which attracts the conductive member by suction.

Also the conductive member supply method of the present invention, according to a second aspect, includes, in the separating step, a step of executing vacuum suction from the first gas-passing aperture communicating with the internal space.

Also the conductive member supply method of the present invention, according to a third aspect, includes, in the alignment step, a step of executing vacuum suction from the second gas-passing aperture communicating with the alignment path.

The air or gas to be supplied from the gas supply unit is preferably a nitrogen-containing gas or the like, in order to prevent oxidation of the conductive member.

The present invention may be realized by in various forms, without departing from the basic characteristics thereof. The aforementioned embodiments are therefore exclusively for explanatory purpose, and are not to restrict the present invention.

This application claims priority from Japanese Patent Applications No. 2006-226444 filed Aug. 23, 2007 and No. 2007-172109 filed on Jun. 29, 2007, which are hereby incorporated by references herein.

What is claimed is:

1. A conductive member supply apparatus for supplying conductive members one by one, comprising:
a reservoir portion including an internal space in which the conductive members are stored and a first gas-passing aperture communicating with the internal space;
an alignment portion including an alignment path in which the conductive members are arranged in a row and which communicates with the internal space, and a second gas-passing aperture communicating with the alignment path;
a stopper for closing/opening the alignment path;
first gas supply unit which supplies gas to the alignment path from the first gas-passing aperture and through the internal space;
second gas supply unit which supplies gas to the alignment path from the second gas-passing aperture; and
control unit which activates the first gas supply unit in a state where the stopper is closed, to introduce the conductive members into the alignment path, and which activates the second gas supply unit to supply the alignment path with gas,
wherein a distance between the second gas-passing aperture and the stopper along a direction of the alignment is substantially within a range of from a dimension of one conductive member to a dimension of one and a half conductive members.

2. The conductive member supply apparatus according to claim 1, wherein gas is supplied by the second gas supply unit from the second gas-passing aperture into the alignment path, to separate, among the conductive members arranged in a row, a first conductive member at the head of the row and in contact with the stopper from a succeeding second conductive member.

3. The conductive member supply apparatus according to claim 2, further comprising first suction unit which provides the internal space with a suction force through the first gas-passing aperture provided in the reservoir portion.

4. The conductive member supply apparatus according to claim 2, further comprising second suction unit which provides the interior of the alignment path with a suction force, through the second gas-passing aperture provided in the alignment path.

5. The conductive member supply apparatus according to claim 3, further comprising second suction unit which provides the interior of the alignment path with a suction force, through the second gas-passing aperture provided in the alignment path.

6. The conductive member supply apparatus according to claim 2, wherein the stopper and the alignment path are constituted of a nozzle capable of attracting the conductive member by suction.

7. A conductive member supply method for supplying conductive members, stored in an internal space of a reservoir portion, one by one from an alignment path of an alignment portion communicating with the internal space, the method comprising:
an alignment step of supplying, in a state where the alignment path is closed by a stopper, gas to the conductive members stored in the internal space from a first gas-passing aperture communicating with the internal space, thereby arranging the conductive members in a row in the alignment path of the alignment portion;
a separation step of supplying gas to the conductive members aligned in the alignment step, in an aligning direction of the conductive members from a second gas-passing aperture which communicates with the alignment path and of which distance from the stopper in the aligning direction of the conductive members is within a range of from a dimension of one conductive member to a dimension of one and a half conductive members, thereby separating one conductive member; and
a step of opening the stopper and supplying gas from the second gas-passing aperture, thereby discharging the one conductive member.

8. The conductive member supply method according to claim 7, wherein the separation step includes a step of executing a vacuum suction from the first gas-passing aperture communicating with the internal space.

9. The conductive member supply method according to claim 7, wherein the alignment step includes a step of executing a vacuum suction from the second gas-passing aperture communicating with the alignment path.

10. The conductive member supply method according to claim 8, wherein the alignment step includes a step of executing a vacuum suction from the second gas-passing aperture communicating with the alignment path.
